(19) United States
(12) Patent Application Publication
(10) Pub. No.: US 2025/0343511 A1
(43) Pub. Date: Nov. 6, 2025

(54) MIXER FOR PROVIDING COMPENSATING CURRENT IN DC BIAS LOOP

(71) Applicant: SKYWORKS SOLUTIONS, INC., Irvine, CA (US)

(72) Inventors: Vinay Kundur, Milpitas, CA (US); Troy Shane Morin, San Diego, CA (US)

(21) Appl. No.: 19/194,810

(22) Filed: Apr. 30, 2025

Related U.S. Application Data
(60) Provisional application No. 63/641,108, filed on May 1, 2024.

(51) Int. Cl. H03D 7/14

(52) U.S. Cl. CPC H03D 7/1425

(57) ABSTRACT

A current mixer is including a mixing section including a first impedance, a second impedance, a first transistor coupled to the first impedance, a second transistor coupled to the second impedance, a third transistor coupled to the first impedance, a fourth transistor coupled to the second impedance, a fifth transistor coupled to the first and second impedance, a sixth transistor coupled to the third and fourth impedance, a seventh transistor coupled to the first impedance and to the first transistor, and an eighth transistor coupled to the second impedance and fourth transistor; and a replica path including a first replica transistor, a second replica transistor coupled to the first replica transistor, and a third replica transistor coupled to the first replica transistor.

### CROSS-REFERENCE TO RELATED APPLICATIONS

This application claims priority under 35 U.S.C. § 119 (e) to U.S. Provisional Application 63/641,108, titled MIXER FOR PROVIDING COMPENSATING CURRENT IN DC BIAS LOOP, filed on May 1, 2024, which is hereby incorporated by reference in its entirety for all purposes.

### BACKGROUND

### 1. Field of the Disclosure

At least one example in accordance with the present disclosure relates generally to telecommunication devices and audio devices such as wireless headphones, earpieces, hearing aids, and so forth.

### 2. Discussion of Related Art

Telecommunication modules may include an antenna for receiving and transmitting signals. The signals may be processed to amplify or attenuate the signals and to filter frequency components of the signals.

### SUMMARY

According to at least one aspect of the present disclosure a current mixer is provided, comprising a mixing section including a first impedance, a second impedance, a first transistor coupled to the first impedance, a second transistor coupled to the second impedance, a third transistor coupled to the first impedance, a fourth transistor coupled to the second impedance, a fifth transistor coupled to the first and second impedance, a sixth transistor coupled to the third and fourth impedance, a seventh transistor coupled to the first impedance and to the first transistor, and an eighth transistor coupled to the second impedance and fourth transistor; and a replica path including a first replica transistor, a second replica transistor coupled to the first replica transistor, and a third replica transistor coupled to the first replica transistor.

In some examples, the current mixer further comprises a high voltage node and a low voltage node, wherein the high voltage node is coupled to the seventh transistor, the eighth transistor, and the first replica transistor, and the low voltage node is coupled to the second replica transistor, third transistor, seventh transistor, and eighth transistor. In some examples, the current mixer further comprises a first local oscillator connection coupled to a gate of the first transistor and a gate of the fourth transistor and configured to provide a first time-varying signal to the gate of the first transistor and the gate of the fourth transistor. In some examples, the current mixer further comprises a second local oscillator connection coupled to a gate of the second transistor and a gate of the third transistor and configured to provide a second time-varying signal to the gate of the second transistor and to the gate of the third transistor. In some examples, the current mixer further comprises a first RF connection coupled to a gate of the fifth transistor and a gate of the second replica transistor, and configured to provide a third time-varying signal to the gate of the fifth transistor and the gate of the second replica transistor. In some examples, the current mixer further comprises a second RF connection coupled to a gate of the sixth transistor and a gate of the third replica transistor, and configured to provide a fourth time-varying signal to the gate of the sixth transistor and the gate of the third replica transistor. In some examples, the third time-varying signal and the fourth time-varying signal are substantially identical and 180 degrees out of phase. In some examples, the current mixer further comprises a control node coupled to a gate of the first replica transistor, a gate of the seventh transistor, and a gate of the eighth transistor. In some examples, the first time-varying signal and the second time-varying signal are substantially identical and 180 degrees out of phase. In some examples, the current mixer further comprises a capacitor coupled in parallel with the first replica transistor between a high voltage node, and the second replica transistor and the third replica transistor.

According to at least one aspect of the present disclosure, a current mixer is provided, comprising a high voltage node; a low voltage node; a first plurality of transistors coupled to the high voltage node; a second plurality of transistors coupled to the low voltage node; and a third plurality of transistor coupled to the first plurality of transistors and to the second plurality of transistors.

In some examples, the first plurality of transistors includes a first transistor, a second transistor, and a third transistor, respective first drains or sources of the first transistor, second transistor, and third transistor being coupled to the high voltage node. In some examples, the second plurality of transistors includes a fourth transistor, a fifth transistor, a sixth transistor, and a seventh transistor, respective first drains or sources of the first and second transistors being coupled to a second drain or source of the first transistor, and respective second drains of the fourth, fifth, sixth, and seventh transistors being coupled to the low voltage node. In some examples, the third plurality of transistors includes an eighth transistor, ninth transistor, tenth transistor, and eleventh transistor, respective first drains or sources of the eighth and tenth transistor being coupled to a second drain or source of the third transistor, respective first drains or sources of the second and ninth and eleventh transistors being coupled to a second drain or source of the third transistor, respective second drains or sources of the eighth and ninth transistors being coupled to a first drain or source of the sixth transistor, and respective second drains or sources of the tenth and eleventh transistors being coupled to a first drain or source of the seventh transistor. In some examples, the current mixer further comprises a first impedance and a second impedance, the first impedance coupled to each drain and source of the second transistor, and the second impedance coupled to each drain and source of the third transistor. In some examples, the current mixer further comprises a first node configured to provide a first time-varying signal to respective gates of the eight transistor and the eleventh transistor. In some examples, the current mixer further comprises a second node configured to provide a second time-varying signal to respective gates of the ninth transistor and tenth transistor. In some examples, the current mixer further comprises a third node configured to provide a third time-varying signal to respective gates of fourth transistor and sixth transistor. In some examples, the current mixer further comprises a fourth node configured to provide a fourth time-varying signal to respective gates of the fifth transistor and seventh transistor. In some examples, the current mixer further comprises a fifth node coupled to respective gates of the first transistor, second transistor, and third transistor.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a receive path of a circuit according to an example;

FIG. 2 illustrates a current mixer according to an example;

FIG. 3 illustrates a current mixer according to an example; and

FIG. 4 illustrates a graph according to an example.

### DETAILED DESCRIPTION

In mixer circuits with no common mode current and no source degeneration, mixer current increases with input radio frequency (RF) power (e.g., at the antenna or at a transmit node). The increased mixer current changes the output common mode current and increases overall power consumption. In mixer circuits (e.g., located in the telecommunication signal chain of a telecommunication module) common mode current source and/or source degeneration may be used to control the excess current. However, these solutions require additional headroom for higher voltages, reduce gain (e.g., in the mixer), and increase noise in the signal chain.

According to aspects of the present disclosure, a mixer is presented which absorbs the increased current in the mixer branch, thereby preventing or limiting excess mixer current from propagating further along the signal chain. By preventing the propagation of the mixer current, the overall power consumption of the further stages may be reduced. Furthermore, by absorbing the excess mixer current, the need for common mode current sourcing and/or source degeneration may be reduced or eliminated. According to aspects of the present disclosure, examples of the mixer track input power through a replica path and mirrors this power to load devices to absorb the increased current in mixer branches.

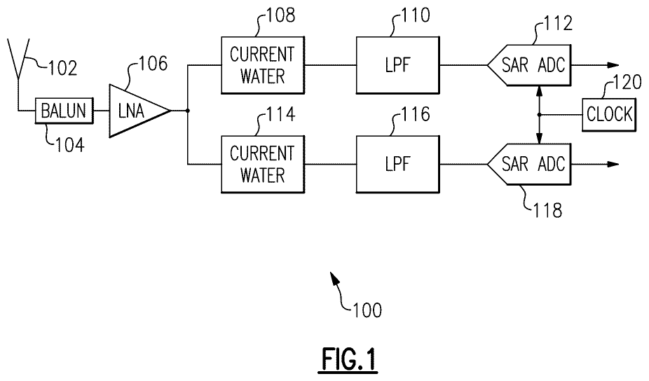

FIG. 1 illustrates a receive path 100 in a telecommunication module, such as a front-end module (FEM). The receive path 100 includes an antenna 102, a balun 104, a low noise amplifier 106 (“LNA 106”), a first current mixer 108, a first low pass filter 110, a first successive approximation register analog-to-digital converter 112 (“first SAR ADC 112”), a second current mixer 114, a second low pass filter 116, a second SAR ADC 118, and a clock 120. In some examples, the first current mixer 108, first low pass filter 110, and first SAR ADC 112 may be part of an “I” channel, and the second current mixer 114, second low pass filter 116, and second SAR ADC 118 may be part of a “Q” channel, where the I channel processes the cosine components of the sinusoidal signal, and the Q channel processes the sine components of a sinusoidal signal (the sinusoidal signal being, for example, the signal received by the antenna 102).

The receive path 100 may receive a signal at the antenna 102, mix portions of that signal with current from the current mixers, filter out undesirable frequency elements of the signal, and then convert the signal from analog to digital form to be provided to a receiving device (such as a computer, headphones, audio hardware, or any other type of circuit).

The antenna 102 is coupled to the balun 104. The balun 104 is coupled to the LNA 106. The LNA 106 is coupled to the first current mixer 108 and to the second current mixer 114. The first current mixer 108 is coupled to the first low pass filter 110. The first low pass filter 110 is coupled to the first SAR ADC 112. The second current mixer 114 is coupled to the second low pass filter 116. The second low pass filter 116 is coupled to the second SAR ADC 118. The clock 120 is coupled to the first SAR ADC 112 and the second SAR ADC 118.

The antenna 102 is configured to receive a sinusoidal signal and provide the signal to the balun 104. The balun 104 may balance the signal (e.g., convert the signal from single-ended to differential, or differential to single-ended, and so forth), and may provide the signal to the LNA 106. The LNA 106 is an amplifier and may amplify one or more frequency components of the signal and/or the entire signal. The LNA 106 may be configured to amplify the signal without adding much noise to the signal and/or without amplifying noise in the signal. The LNA 106 may have a differential output, or a single-ended output, and may provide the signal to the first current mixer 108 and/or the second current mixer 114.

The first current mixer 108 may receive the signal and mix a current with the current corresponding to the signal. In this example, the first current mixer 108 is part of the I-channel of the receive path 100. As a result, in some examples, the first current mixer 108 may modulate or demodulate the signal from the LNA 106 according to a given modulation scheme (e.g., amplitude modulation, frequency modulation, phase modulation, amplitude, phase, and frequency key shifting, and so forth). In effect, the first current mixer 108 may be isolating, amplifying, or selecting components of the signal corresponding to a given component sinusoid of the signal. Once the first current mixer 108 has modulated or demodulated the signal, the first current mixer 108 may provide the signal to the first low pass filter 110.

The first low pass filter 110 is a low pass filter, meaning it permits components of the signal having frequencies under a given threshold to be passed on to the first SAR ADC 112, while components having frequencies over the threshold are attenuated or rerouted (e.g., being rerouted to a reference node, such as ground). While a low pass filter is used in this example, bandpass, band reject, high pass filters, and other types of filters may be used instead and/or in addition to low pass filters. The first low pass filter 110 provides the components of the signal that are permitted to pass to the first SAR ADC 112.

The first SAR ADC 112 receives the signal from the first low pass filter 110 and converts the signal to digital form. The first SAR ADC 112 may sample the signal based on one or more characteristics of the signal (e.g., voltage, current, frequency, phase, and so forth). Depending on the sampled value, the first SAR ADC 112 may then assign a value to the signal and store that value in a register. In some examples, the first SAR ADC 112 may be used to measure the characteristics of the signal over a period of time, and the measured value may then be stored (e.g., in a register) and/or output to another device. In some examples, the first SAR ADC 112 may have a bit-width, e.g., 10 bits, more than 10 bits, less than 10 bits, and so forth. The first SAR ADC 112 may provide the digitized sample of the signal to another device, such as an audio processing unit, a computer, headphones, and so forth.

The second current mixer 114 may receive the signal and mix a current with the current corresponding to the signal. In this example, the second current mixer 114 is part of the Q-channel of the receive path 100. As a result, in some examples, the second current mixer 114 may modulate or demodulate the signal from the LNA 106 according to a given modulation scheme (e.g., amplitude modulation, frequency modulation, phase modulation, amplitude, phase, and frequency key shifting, and so forth). In effect, the second current mixer 114 may be isolating, amplifying, or selecting components of the signal corresponding to a given component sinusoid of the signal. Once the second current mixer 114 has modulated or demodulated the signal, the second current mixer 114 may provide the signal to the second low pass filter 116.

The second low pass filter 116 is a low pass filter, meaning it permits components of the signal having frequencies under a given threshold to be passed on to the second SAR ADC 118, while components having frequencies over the threshold are attenuated or rerouted (e.g., being rerouted to a reference node, such as ground). While a low pass filter is used in this example, bandpass, band reject, high pass filters, and other types of filters may be used instead and/or in addition to low pass filters. The second low pass filter 116 provides the components of the signal that are permitted to pass to the second SAR ADC 118.

The second SAR ADC 118 receives the signal from the second low pass filter 116 and converts the signal to digital form. The second SAR ADC 118 may sample the signal based on one or more characteristics of the signal (e.g., voltage, current, frequency, phase, and so forth). Depending on the sampled value, the second SAR ADC 118 may then assign a value to the signal and store that value in a register. In some examples, the second SAR ADC 118 may be used to measure the characteristics of the signal over a period of time, and the measured value may then be stored (e.g., in a register) and/or output to another device. In some examples, the second SAR ADC 118 may have a bit-width, e.g., 10 bits, more than 10 bits, less than 10 bits, and so forth. The second SAR ADC 118 may provide the digitized sample of the signal to another device, such as an audio processing unit, a computer, headphones, and so forth.

The clock 120 provides a clock signal to the first SAR ADC 112 and/or the second SAR ADC 118. The clock signal may be used to drive the SAR ADCs 112, 118 and/or determine the timing of the SAR ADCs 112, 118.

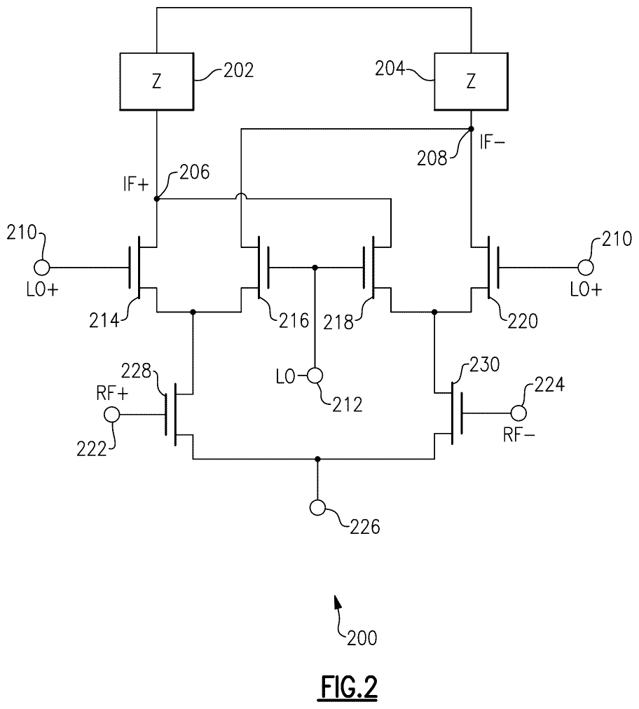

FIG. 2 illustrates a current mixer 200 according to an example. The current mixer 200 includes a first resistor 202, a second resistor 204, a first output node 206 (“first output 206”), a second output node 208 (“second output 208”), a first node 210, a second node 212, a first transistor 214, a second transistor 216, a third transistor 218, a fourth transistor 220, a third node 222, a fourth node 224, a fifth node 226, a fifth transistor 228, and a sixth transistor 230.

The first and second resistors 202, 204 may be coupled to a high voltage node, such as a VDD node. The first resistor 202 is coupled to the first output 206. The second resistor 204 is coupled to the second output 208. The first output 206 is coupled to a first drain or source of the first transistor 214 and to a first drain or source of the third transistor 218. The second output 208 is coupled to a first drain or source of the second transistor 216 and to a first drain or source of the fourth transistor 220. Respective second drains or sources of the first and second transistors 214, 216 are coupled to the first drain or source of the fifth transistor 228. Respective second drains or sources of the third and fourth transistors 218, 220 are coupled to the first drain or source of the sixth transistor 230. Respective second drains or sources of the fifth and sixth transistors 228, 230 are coupled to the fifth node 226. The first node 210 is coupled to the respective gates of the first and fourth transistors 214, 220. The second node 212 is coupled to the respective gates of the second and third transistors 216, 218. The third node 222 is coupled to the gate of the fifth transistor 228. The fourth node 224 is coupled to the gate of the sixth transistor 230.

The first node 210 may be configured to provide an output voltage from a local oscillator; the output voltage may be time varying. The second node 212 is configured to provide and output voltage from a local oscillator; the output voltage may be time varying and may, in some examples, be 180 degrees out of phase (but otherwise similar or identical) to the output voltage provided by the first node 210.

The third node 222 may be configured to provide a voltage based on the RF input signal; the voltage may be time varying. The fourth node 224 may be configured to provide a voltage based on the RF input signal; the voltage may be time varying and may, in some examples, be 180 degrees out of phase (but otherwise similar or identical) to the voltage provided by the third node 222.

The fifth node 226 may be configured to provide a reference or low voltage, such as a lowest voltage in the current mixer 200 (e.g., VSS).

The current mixer 200 may have an output, measured at the first and second output nodes 206, 208, where the output is a mix of the signals provided to the gates of the transistors via the nodes 210, 212, 222, 224. In some examples, the output may be measured as the difference between the output nodes 206, 208, and may be equal to a difference in the voltage between the first and second nodes 210, 212 multiplied by a difference in the voltage between the third and fourth nodes 222, 224, and in some examples, said product may be further modified by a scaling coefficient.

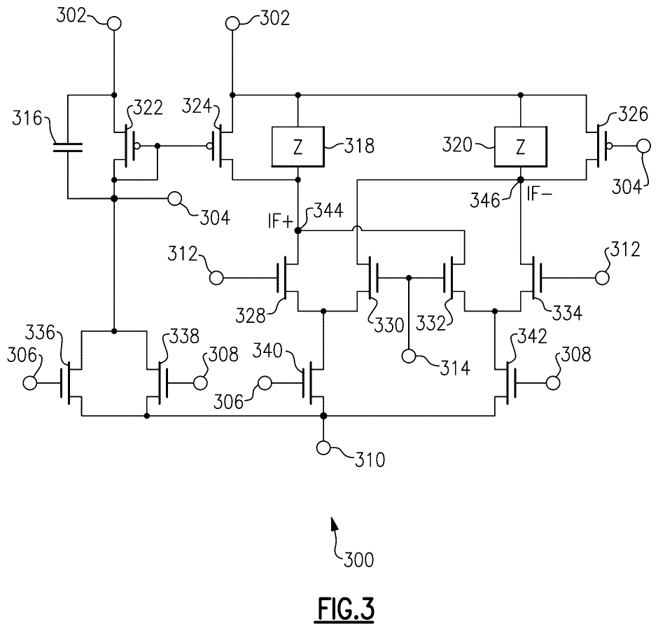

FIG. 3 illustrates a current mixer 300 according to an example. The current mixer 300 includes a first node 302, a second node 304, a third node 306, a fourth node 308, a fifth node 310, a sixth node 312, a seventh node 314, a capacitor 316, a first impedance 318, a second impedance 320, a first transistor 322, a second transistor 324, a third transistor 326, a fourth transistor 328, a fifth transistor 330, a sixth transistor 332, a seventh transistor 334, an eighth transistor 336, a ninth transistor 338, a tenth transistor 340, an eleventh transistor 342, a first intermediate frequency node 344 (“first IF node 344”), and a second intermediate frequency node 346 (“second IF node 346”). The current mixer 300 may be a balanced double-ended current mixing circuit in some examples (e.g., may have a differential output).

The first node 302 is coupled to a first drain or source of the first transistor 322 and second transistor 324, as well as the first impedance 318, the second impedance 320, the capacitor 316, and a first drain or source of the third transistor 326. The second node 304 is coupled to the capacitor 316, a second drain or source of the first transistor 322, the gate of the first transistor 322, the gate of the second transistor 324, the gate of the third transistor 326, a first drain or source of the eighth transistor 336, and a first drain or source of the ninth transistor 338. The third node 306 is coupled to a gate of the eighth transistor 306 and a gate of the tenth transistor 340. The fourth node 308 is coupled to a gate of the ninth transistor 338 and to a gate of the eleventh transistor 342. The fifth node 310 is coupled to a respective second drain or source of the eighth transistor 336, ninth transistor 338, tenth transistor 340, and eleventh transistor 342. The sixth node 312 is coupled to a gate of the fourth transistor 328 and a gate of the seventh transistor 334. The seventh node 314 is coupled to a gate of the fifth transistor 330 and a gate of the sixth transistor 332. The second transistor 324 is coupled in parallel with the first impedance 318—in some examples, the first and second drain and/or sources of the second transistor 324 are coupled to the first impedance 318. The first drain or source of the second transistor 324 is coupled to the second impedance 320 and the first drain or source of the third transistor 326. The second drain or source of the second transistor 324 is coupled to a first drain or source of the fourth transistor 328 and a first drain or source of the sixth transistor 332. The second drain or source of the third transistor 326 is coupled to the first drain or source of the fifth transistor 3304 and the first drain or source of the seventh transistor 334. The third transistor 326 is coupled in parallel with the second impedance 320—in some examples, the first and second drains and/or sources of the third transistor 326 are coupled to the second impedance 320. The first drain or source of the third transistor 326 is coupled to the first impedance 318. The second drain or source of the fourth transistor 328 and the second drain or source of the fifth transistor 330 are coupled to the first drain or source of the tenth transistor 340. The second rain or source of the sixth transistor 332 and the second drain or source of the seventh transistor 334 are coupled to the first drain or source of the eleventh transistor 342. The first IF node 344 may be coupled to a respective first drain or source of the fourth transistor 328 and the fifth transistor 332. The second IF node 346 may be coupled to a respective first drain or source of the fifth transistor 330 and seventh transistor 334.

The first node 302 may be coupled to and/or configured to provide a highest voltage or high voltage (such as VDD). The second node 304 may have a voltage Vbp (which may be constant or variable). The third node 306 may have or be configured to provide a positive radio frequency voltage (RF+), and the fourth node 308 may have or be configured to provide a negative radio frequency voltage (RF−). The fifth node 310 may be coupled to and/or configured to provide a lowest or low voltage (such as VSS). The sixth node 312 may have or be configured to provide a positive or high voltage of the local oscillator (LO+), and the seventh node 314 may have or be configured to provide a negative or low voltage of the local oscillator (LO−).

The capacitor 316 may be configured as a filter cap to remove RF signal from the second node 304.

With respect to the transistors, the first transistor 322, second transistor 324, and third transistor 326 may be one type of transistor (e.g., pMOS or nMOS), while the fourth through eleventh transistors 328-342 may be of the opposite or other type (e.g., if the first three transistors are pMOS, then the other seven transistor are nMOS).

The local oscillator voltages, LO+ and LO−, may be based on the sum and/or difference of the frequencies of the input signal and the local oscillator's signal (e.g., the local oscillator's voltage). LO− and LO+ may be used for heterodyning of the signals.

The RF voltages RF+ and RF− may correspond to the voltages of the input signal (e.g., the radio signal being received on the antenna and provided to the current mixer 300 via the LNA 106 for mixing). Thus, in some examples, the local oscillator voltages LO+ and LO− are used to control the frequency conversion (e.g., modulation or demodulation) of the RF signal.

The first IF node voltage, IF+, and the second IF node voltage, IF−, may be outputs of the current mixer 300. That is, in some examples, the first IF node 344 and second IF node 346 are outputs of the current mixer 300.

The eighth transistor 336 and ninth transistor 338 may be part of a replica path, the replica path being a path that tracks DC current shifts due to the RF signal (e.g., due to RF+ and RF−). As a result, the eighth transistor 336, ninth transistor 338, and/or any other transistors that are part of the replica path may be referred to as “replica transistors.” The DC current shifts are filtered and mirrored to Vbp (e.g., to second node 304). This, in turn, causes a current from the first node 302 across the impedances 318, 320, thereby providing additional current and/or power to the first IF node 344 and second IF node 346 as the current shifts due to changes in the RF input signal power.

In the current mixer 300, the values of IF+ and IF− are, in some examples, proportional to the product of the difference between LO+ and LO− and the difference between RF+ and RF−. That is:

$$RF = {RF}^{+} - {RF}^{-} \qquad ( 1 )$$

$$LO = {LO}^{+} - {LO}^{-} \qquad ( 2 )$$

$$IF = {IF}^{+} - {IF}^{-} = k \cdot RF \cdot LO \qquad ( 3 )$$

where IF is the difference between IF+ and IF− and k is a scaling coefficient indicating the proportionality of IF with respect to RF and LO. In some examples, k may also depend on Vbp.

The eighth transistor 336 and ninth transistor 338 can cause the output (IF) of the current mixer 300 to change depending on the state of the transistors. Note that the eighth transistor 336 is coupled to the third node 306 and therefore RF+, while the ninth transistor 338 is coupled to the fourth node 308 and therefore RF−. In some examples, RF+ and RF− may vary with time, for example, RF+ may increase to a first maximum value and/or decrease to a first minimum value, and RF− may also increases to a second maximum value and/or decrease to a second minimum value. In some examples, the first and second maximum and minimum values may be the same, while in other examples they may be different. Note that the eighth transistor 336 and ninth transistor 338 are both of the same type (in this example, nMOS). As a result, both the eighth transistor 336 and ninth transistor 338 can be closed (e.g., turned on) when their gate voltages exceed a threshold voltage, or, alternatively, when their gate voltages fall below a threshold voltage. For the purpose of explanation, it may be assumed that the eighth transistor 336 and ninth transistor 338 are both nMOS and are matched (meaning that they have the same turn-on voltage). As a result, both the eighth transistor 336 and ninth transistor 338 may turn on when the gate voltage exceeds a threshold voltage. If RF+ and RF− are both sinusoids that are identical but 180 degrees out of phase, then the eighth transistor 336 will be turned on when RF+ exceeds the threshold voltage, and the ninth transistor 338 will be turned on when RF-exceeds the threshold voltage. This implies, though does not require, that both the eighth and ninth transistor 336, 338 will turn on for approximately the same amount of time at predictable, approximately constant intervals of time. It also implies, but does not require, that the eighth and ninth transistors 336, 338 will not generally be on at the same time (unless the threshold voltage is below the lowest voltage of both RF+ and RF−). The total “on” time of the transistors may be determined by the threshold voltage for turning the transistors on, and may be any value between 100% of the time and 0% of the time, though in some examples will be between 25% of the time and 75% of the time.

When either of the eighth transistor 336 or ninth transistor 338 is on, the second node 304 and fifth node 310 are coupled together. That is, treating the eighth and ninth transistors 336, 338 as switches, when either of those switches are closed, the second node 304 and fifth node 310 are shorted together. As a result, the voltage of the second node 304 is pulled down to substantially equal the voltage of the fifth node 310. That is, in some examples, the voltage at the second node 304 may be equal or approximately equal to VSS.

Continuing with this example, note that the second transistor 324 and third transistor 326 are both of the opposite type to the eighth and ninth transistors 336, 338. In this example, the second and third transistors 324, 326 are therefore pMOS transistors. In contrast to nMOS transistors, pMOS transistors are turned on when the voltage falls below a threshold voltage. The threshold voltage of the pMOS transistors may be unrelated to the threshold voltage of the nMOS transistors (e.g., the two threshold may be completely different and/or unrelated values). The voltage at the fifth node 310 will generally be below the threshold voltage for the pMOS transistors. As a result, the voltage at the gates of the second and third transistors 324, 326 will, in some examples, be pulled down to below the threshold voltage, causing the second and third transistors 324, 326 to be on (e.g., closed). If the second and third transistors 324, 326 are closed, then the first node 302 is shorted to the first IF node 344 and second IF node 346, essentially pulling both IF nodes 344, 346 up to the voltage at the first node 302 (e.g., VDD). Recall from equation (3) that IF equals IF+plus IF−. If the IF nodes 344, 346 are pulled up to VDD, then IF+=IF− and thus IF=0. The output differential is thus minimized, reducing the output of the current mixer 300 and reducing the amount of power propagated down the chain (e.g., to the low pass filters 110, 116 and/or SAR ADCs 112, 118 of FIG. 1, and/or other circuit components coupled, e.g., to the SAR ADCs 112, 118).

Accordingly, in some examples, the current mixer 300 may have eighth and ninth transistors 336, 338 with threshold voltages chosen to create a duty cycle that periodically reduces the output voltage of the current mixer 300 (IF) to zero to reduce the amount of power propagated to components along the chain (e.g., along the I or Q channels). Note further that, in the example provided, the eighth and ninth transistors 336,338 may be on when the voltage of RF+ and/or RF− is relatively high, which may correspond to periods of time when the overall power of the RF signal (e.g., the input signal) is relatively high.

The current mixer 300 may be one example implementation of the first current mixer 108 and/or second current mixer 114 of FIG. 1. In some examples, one current mixer 300 may replace both the first current mixer 108 and the second current mixer 114. In other examples, two current mixers 300 may each respectively replace one of the first and second current mixers 108, 114.

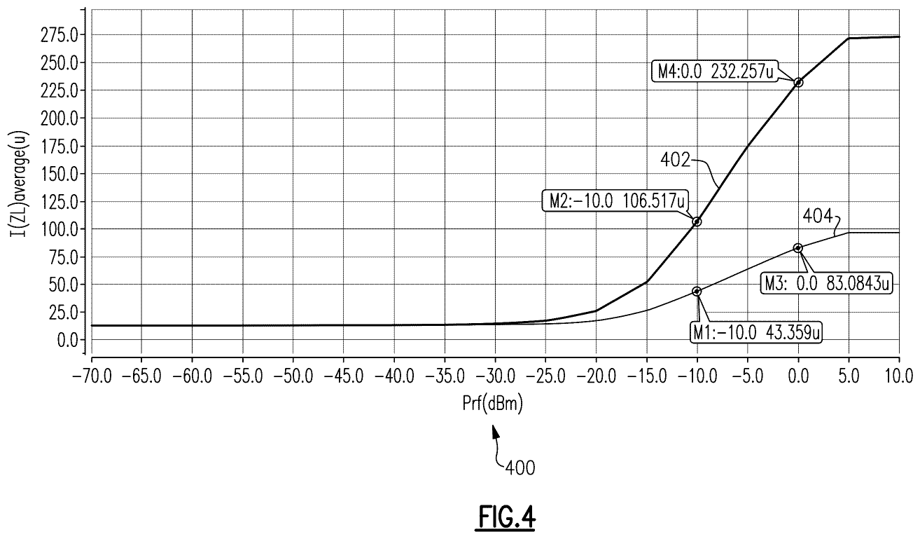

FIG. 4 illustrates a graph 400 of average current through a hypothetical load (such as an audio headset or earpiece). Graph 400 has an X-axis indicating power consumption by the load in decibel-milliwatts, and a Y-axis indicating the average current through the load in micro-Amps (uA). The graph 400 includes a first trace 402 showing state-of-the-art performance, and a second trace 404 showing the performance of systems disclosed herein, including the current mixer 300. As can be seen with reference to the first trace 402, the average load current using existing state-of-the-art solutions is relatively high, ranging from approximately 20 uA at-25.0 dBm and lower, and then increasing to 106.5 uA at −10 dBm, and to 232 uA at 0 dBm. In contrast, as can be seen with reference to the second trace 404, systems disclosed herein achieve approximately 20 uA at −25 dBm and lower, 43 uA at −10 dBm, and 83 uA at 0 dBm. In general, the current through the load also grows at a much faster rate with respect to existing solutions, as shown in the first trace 402, compared to in the systems and methods disclosed herein, as shown with respect to the second trace 404.

As the graph 400 of FIG. 4 indicates, the current mixers disclosed herein (for example, current mixer 300) are able to maintain lower average currents in the load while maintaining higher average voltages and providing an overall reduction in power provided to the load.

Examples of the methods and systems discussed herein are not limited in application to the details of construction and the arrangement of components set forth in the description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

1. A current mixer comprising:
a mixing section including
a first impedance,
a second impedance,
a first transistor coupled to the first impedance,
a second transistor coupled to the second impedance,
a third transistor coupled to the first impedance,
a fourth transistor coupled to the second impedance,
a fifth transistor coupled to the first and second impedance,
a sixth transistor coupled to the third and fourth impedance,
a seventh transistor coupled to the first impedance and to the first transistor, and
an eighth transistor coupled to the second impedance and fourth transistor; and
a replica path including
a first replica transistor,
a second replica transistor coupled to the first replica transistor, and
a third replica transistor coupled to the first replica transistor.

2. The current mixer of claim 1 further comprising a high voltage node and a low voltage node, wherein the high voltage node is coupled to the seventh transistor, the eighth transistor, and the first replica transistor, and the low voltage node is coupled to the second replica transistor, third transistor, seventh transistor, and eighth transistor.

3. The current mixer of claim 2 further comprising a first local oscillator connection coupled to a gate of the first transistor and a gate of the fourth transistor and configured to provide a first time-varying signal to the gate of the first transistor and the gate of the fourth transistor.

4. The current mixer of claim 3 further comprising a second local oscillator connection coupled to a gate of the second transistor and a gate of the third transistor and configured to provide a second time-varying signal to the gate of the second transistor and to the gate of the third transistor.

5. The current mixer of claim 4 further comprising a first RF connection coupled to a gate of the fifth transistor and a gate of the second replica transistor, and configured to provide a third time-varying signal to the gate of the fifth transistor and the gate of the second replica transistor.

6. The current mixer of claim 5 further comprising a second RF connection coupled to a gate of the sixth transistor and a gate of the third replica transistor, and configured to provide a fourth time-varying signal to the gate of the sixth transistor and the gate of the third replica transistor.

7. The current mixer of claim 5 wherein the third time-varying signal and the fourth time-varying signal are substantially identical and 180 degrees out of phase.

8. The current mixer of claim 5 further comprising a control node coupled to a gate of the first replica transistor, a gate of the seventh transistor, and a gate of the eighth transistor.

9. The current mixer of claim 4 wherein the first time-varying signal and the second time-varying signal are substantially identical and 180 degrees out of phase.

10. The current mixer of claim 1 further comprising a capacitor coupled in parallel with the first replica transistor between a high voltage node, and the second replica transistor and the third replica transistor.

11. A current mixer comprising:
a high voltage node;
a low voltage node;
a first plurality of transistors coupled to the high voltage node;
a second plurality of transistors coupled to the low voltage node; and
a third plurality of transistor coupled to the first plurality of transistors and to the second plurality of transistors.

12. The current mixer of claim 11 wherein the first plurality of transistors includes a first transistor, a second transistor, and a third transistor, respective first drains or sources of the first transistor, second transistor, and third transistor being coupled to the high voltage node.

13. The current mixer of claim 12 wherein the second plurality of transistors includes a fourth transistor, a fifth transistor, a sixth transistor, and a seventh transistor, respective first drains or sources of the first and second transistors being coupled to a second drain or source of the first transistor, and respective second drains of the fourth, fifth, sixth, and seventh transistors being coupled to the low voltage node.

14. The current mixer of claim 13 wherein the third plurality of transistors includes an eighth transistor, ninth transistor, tenth transistor, and eleventh transistor, respective first drains or sources of the eighth and tenth transistor being coupled to a second drain or source of the third transistor, respective first drains or sources of the second and ninth and eleventh transistors being coupled to a second drain or source of the third transistor, respective second drains or sources of the eighth and ninth transistors being coupled to a first drain or source of the sixth transistor, and respective second drains or sources of the tenth and eleventh transistors being coupled to a first drain or source of the seventh transistor.

15. The current mixer of claim 14 further comprising a first impedance and a second impedance, the first impedance coupled to each drain and source of the second transistor, and the second impedance coupled to each drain and source of the third transistor.

16. The current mixer of claim 15 further comprising a first node configured to provide a first time-varying signal to respective gates of the eight transistor and the eleventh transistor.

17. The current mixer of claim 16 further comprising a second node configured to provide a second time-varying signal to respective gates of the ninth transistor and tenth transistor.

18. The current mixer of claim 17 further comprising a third node configured to provide a third time-varying signal to respective gates of fourth transistor and sixth transistor.

19. The current mixer of claim 18 further comprising a fourth node configured to provide a fourth time-varying signal to respective gates of the fifth transistor and seventh transistor.

20. The current mixer of claim 19 further comprising a fifth node coupled to respective gates of the first transistor, second transistor, and third transistor.
